(19) United States
(12) Patent Application Publication
(10) Pub. No.: US 2020/0117297 A1
(43) Pub. Date: Apr. 16, 2020

(54) DISPLAY DEVICE

(71) Applicant: Japan Display Inc., Minato-ku (JP)

(72) Inventor: Tomohiko NAGANUMA, Minato-ku (JP)

(73) Assignee: Japan Display Inc., Minato-ku (JP)

(21) Appl. No.: 16/713,065

(22) Filed: Dec. 13, 2019

Related U.S. Application Data
(63) Continuation of application No. PCT/JP2018/020298, filed on May 28, 2018.

(30) Foreign Application Priority Data
Jun. 16, 2017 (JP) 2017-118377

(51) Int. Cl. G06F 3/044; G06F 3/041; H01L 41/113; H01L 41/193

(52) U.S. Cl. CPC G06F 3/044; G06F 3/0412; G06F 2203/04105; H01L 41/193; H01L 41/113

(57) ABSTRACT

A display device according to an embodiment of the present invention includes: an insulation layer having an insulation surface; and a touch sensor provided on an upper surface of the insulation surface; the touch sensor includes a plurality of first electrodes and a plurality of second electrodes provided on the upper surface of the insulation surface forming first electrostatic capacitance, a piezoelectric layer provided on upper surfaces of the plurality of first electrodes and the plurality of second electrodes and charged according to applying a pressing force, a pulse generator applying a pulse voltage to the first electrodes, and a determination circuit detecting a change in the first electrostatic capacitance from a change in a first measurement value caused by the application of the pulse voltage and detecting strength of the pressing force from a change in a second measurement value not caused by the application of the pulse voltage.

### CROSS-REFERENCE TO RELATED APPLICATION

This present application is a continuation-in-part of International Application No. PCT/JP2018/020298, filed in the Japan Patent Office on May 28, 2018, the entire content of which is hereby incorporated by reference. This application claims priority from Japanese application JP 2017-118377 filed on Jun. 16, 2017, the entire content of which is hereby incorporated by reference.

### BACKGROUND OF THE INVENTION

### 1. Field of the Invention

The present invention relates to a display device.

### 2. Description of the Related Art

JP 2012-68724 A discloses a touch sensor that is assumed to be equipped in, for example, an electronic apparatus such as a cellular phone, a smartphone, or a PDA including a display device.

The touch sensor disclosed in JP 2012-68724 A includes a sensor sheet on which the position of an input body such as a finger is detected and a contact substrate on which a pressing force by the input body is detected. The sensor sheet and the contact substrate are provided in separate layers.

The sensor sheet includes a dielectric layer, a first electrode disposed on the upper surface of the dielectric layer, and a second electrode disposed on the lower surface of the dielectric layer, and a driving signal is transmitted from the second electrode to the first electrode. As a conductor such as a finger is closer, the driving signal received by the first electrode is changed based on a change in an electrostatic capacitance between the first and second electrodes. When an electrostatic capacitance detection unit detects the change, the position of the input body is detected.

The contact substrate includes a base substrate, a metal dome provided on the upper surface of the base substrate, and a plurality of contact electrodes. A pressing force of the input body deforms the metal dome and conductive states of the plurality of contact electrodes change with this deformation. When a conduction detection unit detects this change, the pressing force of the input body is detected.

### SUMMARY OF THE INVENTION

In the foregoing configuration of the related art, there is a problem that it is difficult to slim the display device including the touch sensor. That is, the touch sensor includes the sensor sheet and the contact substrate provided in a layer separate from the sensor sheet. Further, the sensor sheet has a three-layered structure including at least the first electrode, the dielectric layer, and the second electrode. Therefore, it is difficult to thin the display device including the touch sensor.

(1) A display device according to an embodiment of the present invention includes: a first substrate; a light-emitting element that is disposed above the first substrate; an insulation layer that has an insulation surface provided above the light-emitting element; and a touch sensor that is provided on an upper surface of the insulation surface; the touch sensor includes a plurality of first electrodes that is provided on the upper surface of the insulation surface, a plurality of second electrodes that is provided on the upper surface of the insulation surface and forms first electrostatic capacitance along with the plurality of first electrodes, a piezoelectric layer that is provided on upper surfaces of the plurality of first electrodes and the plurality of second electrodes and is charged in accordance with application of a pressing force, a pulse generator that applies a pulse voltage to the first electrodes, and a determination circuit that detects a change in the first electrostatic capacitance from a change in a first measurement value related to the second electrodes and caused by the application of the pulse voltage and detects strength of the pressing force from a change in a second measurement value related to the second electrodes and not caused by the application of the pulse voltage.

(2) In the display device described in (1) above, the plurality of first electrodes may include a plurality of groups of the first electrodes in a line form connected in a first direction on a plane formed by the first substrate.

(3) The display device described in (2) above may further include a first selection circuit disposed between the plurality of first electrodes and the pulse generator; the first selection circuit selects one group in order among the plurality of groups of the first electrodes in the line form and applies the pulse voltage from the pulse generator to the selected group of the first electrodes in the line form.

(4) In the display device described in (2) above, in the groups of the first electrodes in the line form connected in the first direction, two first electrodes adjacent to one another may be connected by a first connection portion.

(5) In the display device described in (2) above, the plurality of second electrodes may include a plurality of groups of the second electrodes in a line form connected in a second direction intersecting the first direction on the plane formed by the first substrate.

(6) The display device described in (5) above may further include a second selection circuit disposed between the plurality of second electrodes and the determination circuit; the second selection circuit select one group in order among the plurality of groups of the second electrodes in the line form and transfers a change in a physical amount output from the selected group of the second electrodes in the line form to the determination circuit.

(7) In the display device described in (5) above, in the groups of the second electrodes in the line form connected in the second direction, two second electrodes adjacent to one another may be connected by a second connection portion.

(8) In the display device described in (6) above may further include a second substrate that is provided above the touch sensor; the determination circuit may detect a position of an input body formed from a conductor touched on the second substrate on the plane formed by the first substrate from a selection situation of the first selection circuit, a selection situation of the second selection circuit, and the change in the first measurement value and may detect strength of a pressing force of the input body on the second substrate from the change in the second measurement value.

(9) In the display device described in (1) above, the first and second measurement values may be measured by delaying a timing; the pulse generator may apply the pulse voltage to the first electrodes when the first measurement value is measured, and the pulse generator may not apply the pulse voltage to the first electrodes when the second measurement value is measured.

(10) In the display device described in (1) above, the piezoelectric layer may include at least one of polyvinylidene fluoride, trifluorinated ethylene, and polylactic acid as a constituent material.

(11) The display device described in (1) above may further include a bank that is provided on a lateral surface of the light-emitting element; a space between the first and second electrodes may be located above the bank.

(12) The display device described in (1) above may further include a sealing layer that includes at least an inorganic insulation layer above a plurality of the light-emitting elements; an upper surface of the sealing layer may form the insulation surface.

(13) The display device described in (1) above may further include a display region in which the light-emitting element is provided; the piezoelectric layer may be provided across an entire surface of the display region.

### BRIEF DESCRIPTION OF THE DRAWINGS

FIG. 1 is a perspective view illustrating a display device according to an embodiment.

FIG. 2 is an enlarged view illustrating a portion indicated by the line II of FIG. 1.

FIG. 3 is an enlarged view illustrating the display device illustrated in FIG. 2 by partially omitting a cross-section taken along the line III-III.

FIG. 4 is an enlarged view illustrating the display device illustrated in FIG. 2 by partially omitting a cross-section taken along the line IV-IV.

FIG. 5 is an enlarged view illustrating the display device illustrated in FIG. 2 by partially omitting a cross-section taken along the line V-V.

FIG. 6 is a diagram schematically illustrating a detection circuit in which a touch sensor in the display device according to the embodiment is used.

FIG. 7 is a diagram illustrating a flow of touch sensing of the display device according to the embodiment.

FIG. 8 is a timing chart of an input voltage from a pulse generator in the display device according to the embodiment.

FIG. 9 is a timing chart of a first measurement value by a measurement circuit in the display device according to the embodiment.

FIG. 10 is a sectional view illustrating a state in which a second substrate of the display device according to the embodiment is pressed with an input body such as a finger.

FIG. 11 is a schematic view illustrating a property of a piezoelectric layer in the display device according to the embodiment.

FIG. 12 is a schematic view illustrating a property of the piezoelectric layer in the display device according to the embodiment.

FIG. 13 is a schematic view illustrating a property of the piezoelectric layer in the display device according to the embodiment.

FIG. 14 is a schematic view illustrating a property of the piezoelectric layer in the display device according to the embodiment.

### DETAILED DESCRIPTION OF THE INVENTION

Hereinafter, an embodiment will be described with reference to the drawings. Here, the present invention can be embodied in various forms within the scope of the present invention without departing from the gist of the present invention and is not construed as being limited to content described in embodiment to be exemplified below.

The drawings are illustrated in the width, thickness, shape, and the like of each unit more schematically than in the actual aspect to further clarify the description and merely exemplary, and are not construed as limiting interpretation of the present invention. In the present specification and each drawing, the same reference numerals are given to elements that have functions similar to those described in the previously described drawings and repeated description will be omitted in some cases.

Further, in the detailed description of the embodiment of the present invention, when a positional relationship between a certain structure and another structure is presceribed, “on,” “above,” and “below” refers to not only a case where one structure is positioned directly on or directly below another structure but also a case where still another structure is interposed between the structures unless otherwise stated.

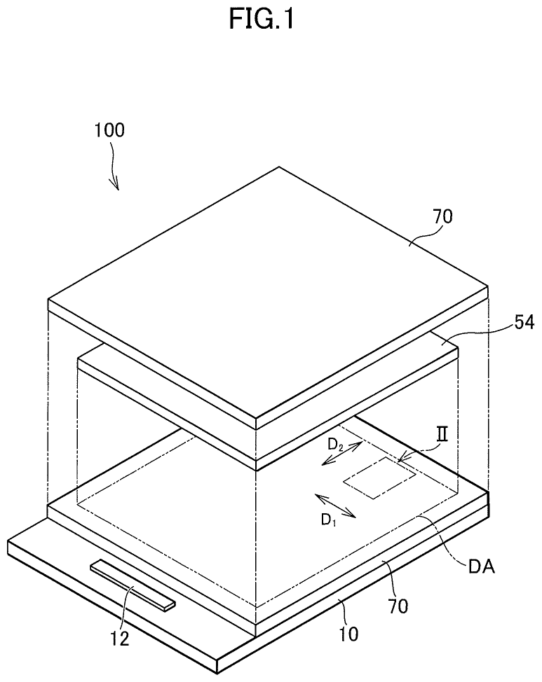

FIG. 1 is a perspective view illustrating a display device 100 according to an embodiment. An organic electroluminescence display device will be exemplified as the display device 100. The display device 100 combines unit pixels (sub-pixels) of a plurality of colors including, for example, red, green, and blue, forms full-color pixels, and displays a full-color image. The display device 100 includes a display region DA in which a plurality of pixels are disposed in a matrix form. The display device 100 includes a touch sensor 54 and the touch sensor 54 is provided to cover the display region DA. The display device 100 includes a first substrate 10. An integrated circuit chip 12 that drives elements displaying an image is mounted on the first substrate 10 and a flexible printed substrate (not illustrated) may be connected for electric connection to the outside.

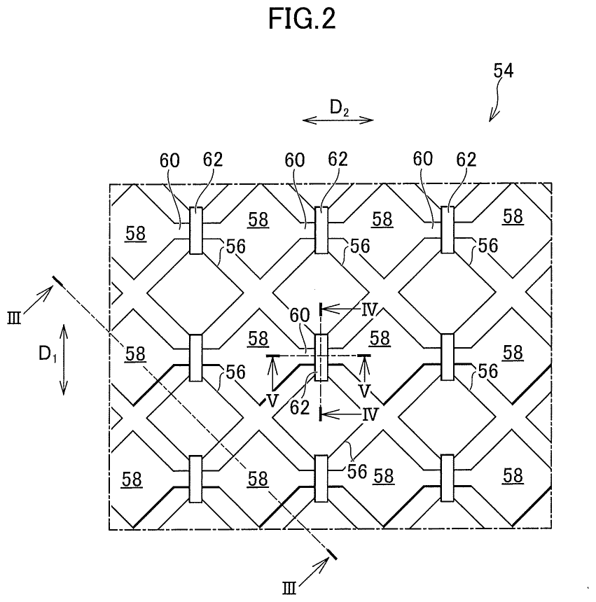

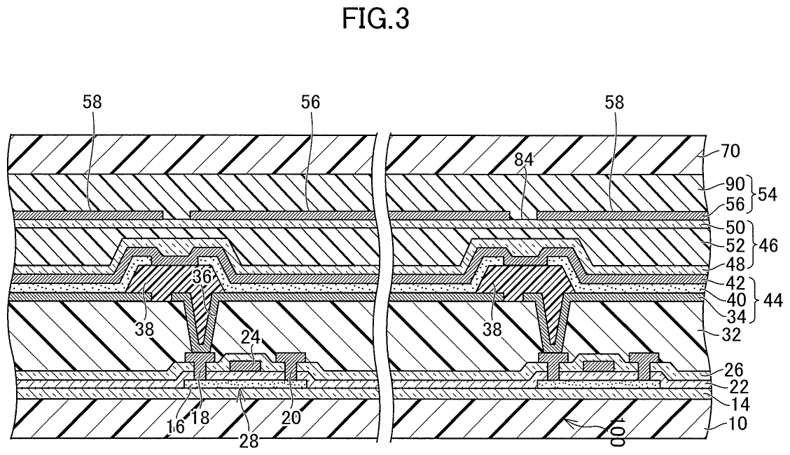

FIG. 2 is an enlarged view illustrating a portion indicated by the line II of FIG. 1. FIG. 3 is an enlarged view illustrating the display device 100 illustrated in FIG. 2 by partially omitting a cross-section taken along the line III-III. The first substrate 10 is formed of resin or glass or may be a film that has flexibility, such as polyimide or polyethylene terephthalate. In the first substrate 10, an undercoat layer 14 serving as a barrier against impurities contained intrinsically is formed. The undercoat layer 14 is formed of a silicon oxide film, a silicon nitride film, or the like and may have a laminate structure thereof. A semiconductor layer 16 is formed over the undercoat layer 14. A gate insulation film 22 is formed over the semiconductor layer 16 to cover the semiconductor layer 16. A gate electrode 24 is formed over the gate insulation film 22 and an inter-layer insulation film 26 is formed to cover the gate electrode 24. A source electrode 18 and a drain electrode 20 are formed through the gate insulation film 22 and the inter-layer insulation film 26 to be electrically connected to the semiconductor layer 16. The semiconductor layer 16, the source electrode 18, the drain electrode 20, and the gate electrode 24 forma thin film transistor 28.

A flattened layer 32 is provided over the thin film transistor 28. A plurality of pixel electrodes 34 configured to correspond to a plurality of unit pixels (sub-pixels), respectively, are provided above the flattened layer 32. In the embodiment, the plurality of pixel electrodes 34 serve as a cathode. When emitted light to be described below is extracted in an opposite direction to the first substrate 10, the pixel electrode 34 may contain a material with high reflectance, such as a metal such as silver, aluminum, or magnesium. That is, a film that contains a conductive material that has transmittance may be formed above a layer with high reflectance. Examples of the material include ITO and IZO. In the flattened layer 32, a surface on which at least the pixel electrode 34 is provided is formed to be flattened. As the flattened layer 32, an organic material such as polyimide or a photosensitive acrylic resin is used in many cases. The pixel electrode 34 is electrically connected to one of the source electrode 18 and the drain electrode 20 on the semiconductor layer 16 by a contact hole 36 formed through the flattened layer 32.

An insulation layer 38 is formed above the flattened layer 32 and the pixel electrode 34. The insulation layer 38 is placed in the margin of the pixel electrode 34 and is formed to open a part (for example, a middle portion) of the pixel electrode 34. A bank surrounding the part of the pixel electrode 34 is formed by the insulation layer 38.

A light-emitting layer 40 is provided above the pixel electrode 34. The light-emitting layer 40 is provided separately for each pixel electrode 34 and a part of the light-emitting layer 40 is provided to be also placed above the insulation layer 38. In the embodiment, each of the plurality of light-emitting layers 40 is configured to emit light of any one color among blue, red, and green corresponding to each pixel. The color corresponding to each pixel is not limited thereto. For example, yellow, white, or the like may also be included. The light-emitting layer 40 is formed by, for example, deposition. The light-emitting layer 40 may be formed on the entire surface covering the display region DA illustrated in FIG. 1 across the plurality of pixels. That is, the light-emitting layer 40 may be formed continuously above the insulation layer 38. When the light-emitting layer 40 is formed across the plurality of pixels, white light is emitted in all the sub-pixels and a desired color wavelength portion is extracted through color filters (not illustrated). In this case, the light-emitting layer 40 can be formed by application of solvent dispersion.

A counter electrode 42 is provided above the light-emitting layer 40. In the embodiment, the counter electrode 42 serves as an anode and is configured as a common electrode formed across the plurality of unit pixels. When emitted light is extracted in the opposite direction to the first substrate 10, for example, a conductive material such as ITO or IZO with transmittance is used. The counter electrode 42 is also disposed above the insulation layer 38 serving as the bank. A light-emitting element 44 that includes the light-emitting layer 40, and the pixel electrode 34 and the counter electrode 42 interposing the light-emitting layer 40 is configured. Each of the plurality of unit pixels includes the light-emitting element 44. The light-emitting layer 40 is interposed between the pixel electrode 34 and the counter electrode 42 and emits light in such a manner that luminance is controlled by a current flowing between both the pixel electrode 34 and the counter electrode 42. At least a hole transport layer and a hole injection layer (not illustrated) may be further provided between the light-emitting layer 40 and the pixel electrode 34. At least one layer of an electron transport layer and an electron injection layer (neither of which illustrated) may be provided between the light-emitting layer 40 and the counter electrode 42.

By covering the light-emitting element 44 with a sealing layer 46 laminated on the counter electrode 42, the light-emitting element 44 is sealed so that moisture is blocked. The sealing layer 46 includes at least an inorganic insulation layer formed of a silicon nitride (SiN) or the like. The sealing layer 46 may have a laminate structure. For example, as illustrated in FIG. 3, the laminate structure may further include a pair of inorganic insulation layers 48 and 50 and at least an organic insulation layer 52 formed of a resin or the like between the inorganic insulation layers 48 and 50. The sealing layer 46 covers the display region DA illustrated in FIG. 1.

The display device 100 according to the embodiment includes the touch sensor 54 on the sealing layer 46. As illustrated in FIGS. 2 and 3, the touch sensor 54 includes a plurality of first electrodes 56, a plurality of second electrodes 58, and a piezoelectric layer 90. The piezoelectric layer 90 may be provided across the entire surface of the display region DA illustrated in FIG. 1. When the piezoelectric layer 90 is provided on the entire surface, patterning of the piezoelectric layer 90 is not necessary, and thus manufacturing cost is reduced. A pressure at the time of pressing can be equally distributed. Thus, it is possible to curb local application of a pressure on the layers below the piezoelectric layer 90, and thus it is possible to curb deterioration in display performance caused due to deterioration in the light-emitting element.

As illustrated in FIG. 3, the plurality of first electrodes 56 are formed above an insulation surface 84 which is an upper surface of the sealing layer 46. For the plurality of first electrodes 56, as illustrated in FIG. 2, the first electrodes 56 adjacent to one another are connected by a first connection portion 62 in a first direction D1 on the plane formed by the first substrate 10, and the first electrodes 56 adjacent to one another are not connected in a second direction D2 intersecting the first direction D1 on the plane formed by the first substrate 10.

As illustrated in FIG. 3, the plurality of second electrodes 58 are formed on the insulation surface 84 which is the upper surface of the sealing layer 46. For the plurality of second electrodes 58, as illustrated in FIG. 2, the second electrodes 58 adjacent to one another are connected in the second direction D2 by a second connection portion 60 provided below the first connection portion 62, and the second electrodes 58 adjacent to one another are not connected in the first direction D1. The second electrodes 58 and the second connection portion 60 are disposed in the same layer. The plurality of first electrodes 56 and the plurality of second electrodes 58 do not overlap one another and are disposed at an interval in the same layer. As illustrated in FIG. 3, the piezoelectric layer 90 is interposed between the first electrode 56 and the second electrode 58.

In the embodiment, as illustrated in FIG. 3, a region between the first electrode 56 and the second electrode 58 adjacent to one another is disposed to be located above the insulation layer 38 forming the bank. When the thickness of the sealing layer 46 is thin and a distance between the light-emitting element 44, and the first electrode 56 and the second electrode 58 is close, optical characteristics can be improved by causing the shape of the first electrode 56 and the shape of the second electrode 58 to correspond to the shape of the pixel. When the thickness of the sealing layer 46 is a certain thickness or more and the light-emitting element 44 is sufficiently separate from the first electrode 56 and the second electrode 58, necessity of forming the first electrode 56 and the second electrode 58 in accordance with the shape of the pixel is low.

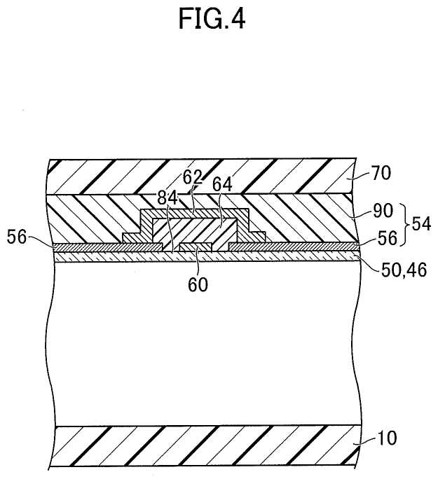

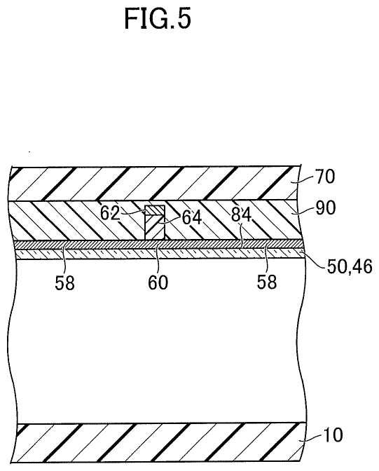

Hereinafter, a connection state of the first electrode 56, the second electrode 58, the first connection portion 62, and the second connection portion 60 will be described in more detail with reference to FIGS. 4 and 5. FIGS. 4 and 5 are enlarged views illustrating the display device 100 illustrated in FIG. 2 by partially omitting a cross-section taken along the lines IV-IV and V-V, respectively.

As illustrated in FIG. 4, the first electrodes 56 adjacent to one another are disposed to be spaced and the second connection portion 60 is disposed between the first electrodes 56 adjacent to one another so that the second connection portion 60 does not to come into contact with the first electrodes 56. An insulation film 64 is provided on parts of the insulation surface 84 exposed from the first electrodes 56 and the second connection portion 60, the upper surface of the ends of the first electrodes 56 adjacent to each other, and the upper surface of the second connection portion 60. The insulation film 64 insulates the first electrodes 56 from the second connection portion 60. Further, the first connection portion 62 is provided on the lateral side and the upper side of the insulation film 64. The first connection portion 62 connects the adjacent first electrodes 56 to one another. The insulation film 64 insulates the first connection portion 62 from the second connection portion 60.

As illustrated in FIG. 5, the second electrode 58 and the second connection portion 60 are disposed on the upper surface of the insulation surface 84. The second connection portion 60 connects the adjacent second electrodes 58 to one another. The insulation film 64 is provided on the upper surface of the second connection portion 60. The insulation film 64 insulates the second connection portion 60 from the first connection portion 62 disposed above the second connection portion 60.

Next, the piezoelectric layer 90 provided above the first electrode 56 and the second electrode 58 will be described in more detail with reference to FIGS. 3, 4, and 5. As illustrated in FIGS. 3, 4, and 5, the piezoelectric layer 90 is continuously formed from regions in which the plurality of first electrodes 56 are formed to regions in which the plurality of second electrodes 58 are formed. The piezoelectric layer 90 covers the exposed upper surfaces and lateral surfaces of the first electrode 56 and the second the electrode 58 and the upper surface and lateral surface of the first connection portion 62.

The piezoelectric layer 90 is configured by binding a film formed of a piezoelectric material. For example, an organic piezoelectric material such as polyvinylidene fluoride (PVDF), trifluorinated ethylene (TrFE), and polylactic acid (PLA) can be used as the piezoelectric material used for the piezoelectric layer 90. Since the piezoelectric material has high transmittance in a visible-light region, the piezoelectric material is used as a material of the piezoelectric layer 90, and thus light emitted from the light-emitting element 44 can transmit through the side of a second substrate 70 without being blocked by the piezoelectric layer 90. Since the exemplified piezoelectric material is an organic material, the piezoelectric material has flexibility. Therefore, even when the display device 100 according to the embodiment is used as a flexible display, the piezoelectric layer 90 has bending resistance, and thus it is possible to curb crack occurrence of the piezoelectric layer 90.

The first electrode 56, the second electrode 58, the first connection portion 62, the second connection portion 60, and the piezoelectric layer 90 described above form the touch sensor 54. A function of the touch sensor 54 will be described below.

As illustrated in FIG. 3, the second substrate 70 is attached to the upper surface of the touch sensor 54, that is, the upper surface of the piezoelectric layer 90. The second substrate 70 is formed of a material such as a resin or glass with high transmittance to a visible-light region, and may include, for example, a cover glass, a polarizing plate, a protective film, or the like or may be a film with flexibility as in the first substrate 10. In the attaching of the second substrate 70, an adhesive (not illustrated) is used.

In the above-described configuration, the display device 100 according to the embodiment contains the touch sensor 54. When a conductor such as a finger is touched on the second substrate 70, the touch sensor 54 can detect a touch position of the conductor such as a finger in a plane direction in the first substrate 10. When an input body such as a finger is pressed on the second substrate 70, the touch sensor 54 can detect strength of a pressing force applied in a lamination direction of the display device 100. Hereinafter, according to the present invention, a method of detecting a touch position of a conductor in the plane direction in the first substrate 10 by the touch sensor 54 in the display device 100 and a method of detecting strength of a pressing force applied from an input body in the lamination direction of the display device 100 will be described.

First, a method of detecting a touch position of a conductor such as a finger in the plane direction in the first substrate 10 will be described. In the embodiment, a principle of a mutual capacitance type is adopted in detection of a touch position of a conductor in the plane direction in the first substrate 10 when the conductor such as a finger is touched on the second substrate 70. In the mutual capacitance type, a touch position of the conductor can be detected by detecting a change in an electrostatic capacitance between the plurality of first electrodes 56 and the plurality of second electrodes 58.

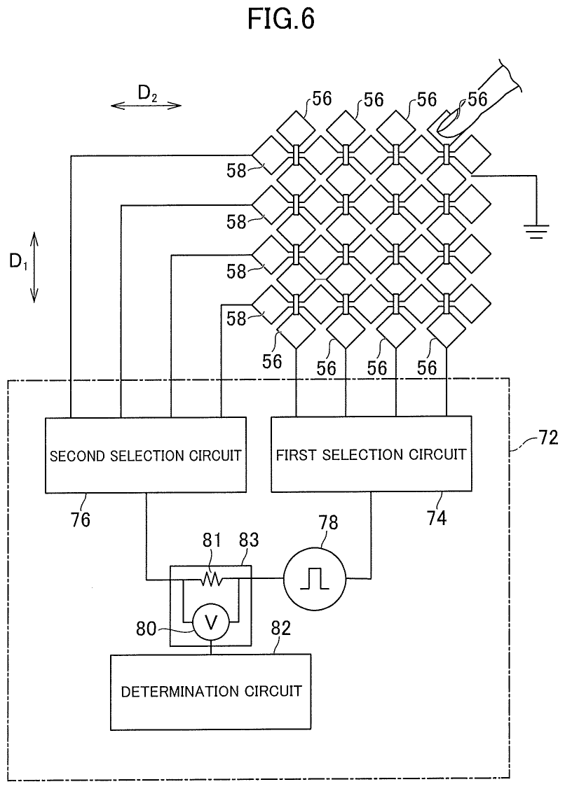

FIG. 6 is a diagram schematically illustrating a detection circuit in which a touch sensor in the display device 100 according to the embodiment is used. The display device 100 includes the plurality of first electrodes 56, the plurality of second electrodes 58, and a sensing circuit 72. The plurality of first electrodes 56 include a plurality of groups of the first electrodes 56 in a line form connected in the first direction D1. The plurality of second electrodes 58 include a plurality of groups of the second electrodes 58 in a line form connected in the second direction D2.

As described above with reference to FIG. 3, the first electrode 56 and the second electrode 58 are disposed to be spaced and the piezoelectric layer 90 is interposed between both the first electrode 56 and the second electrode 58. Accordingly, first electrostatic capacitance is formed between the lateral surface of the first electrode 56 and the lateral surface of the second electrode 58.

The sensing circuit 72 is contained, for example, in the integrated circuit chip 12 illustrated in FIG. 1. The sensing circuit 72 includes a first selection circuit 74, a second selection circuit 76, a pulse generator 78, a measurement circuit 83, and a determination circuit 82.

The first selection circuit 74 included in the sensing circuit 72 is connected to the groups of the first electrodes 56 in the line form connected in the first direction D1. The first selection circuit 74 selects one group of the first electrodes 56 in the line form among the plurality of groups of the first electrodes 56 in the line form. When one group of the first electrodes 56 in the line form is selected for a predetermined period, another group of the first electrodes 56 in the line form is subsequently selected. In this way, all the plurality of groups of the first electrodes 56 in the line form are sequentially scanned.

The second selection circuit 76 included in the sensing circuit 72 is connected to the groups of the second electrodes 58 in the line form connected in the second direction D2. The second selection circuit 76 selects one group of the second electrodes 58 in the line form among the plurality of groups of the second electrodes 58 in the line form. When one group of the second electrodes 58 in the line form is selected for a predetermined period, another group of the second electrodes 58 in the line form is subsequently selected. In this way, all the plurality of groups of the second electrodes 58 in the line form are sequentially scanned.

The pulse generator 78 included in the sensing circuit 72 applies a pulse voltage to the one group of the first electrodes 56 in the line form selected by the first selection circuit 74. Since the first selection circuit 74 selects one group of the first electrodes 56 in the line form during each predetermined period, the pulse voltage from the pulse generator 78 is applied sequentially to each of the plurality of groups of the first electrodes 56 in the line form in response to the selection.

When the pulse voltage is applied to the one group of the first electrodes 56 in the line form selected by the first selection circuit 74, the change in the potential is delivered to the second electrode 58 by coupling based on the first electrostatic capacitance generated between the first electrode 56 and the second electrode 58.

Here, when the conductor such as a finger is touched on the second substrate 70 near a position at which one group of the first electrodes 56 in the line form selected by the first selection circuit 74 crosses one group of the second electrodes 58 in the line form selected by the second selection circuit 76, an electric field is also generated between the first electrode 56 and the conductor touched on the second substrate 70 or between the second electrode 58 and the conductor touched on the second substrate 70 in addition to an electric field between the first electrode 56 and the second electrode 58. The change in the electric field partially deteriorates the coupling between the first electrode 56 and the second electrode 58. That is, the first electrostatic capacitance generated between the first electrode 56 and the second electrode 58 decreases.

The measurement circuit 83 included in the sensing circuit 72 is connected to the second selection circuit 76 and measures a change in a first physical amount caused with a decrease in the first electrostatic capacitance. In the embodiment, the measurement circuit 83 includes a load 81 connected to an output end of the second selection circuit 76 and a voltmeter 80 connected to both ends of the load 81. The voltmeter 80 measures a voltage value generated at both ends of the load 81 caused with a decrease in the first electrostatic capacitance. That is, the first physical amount measured by the measurement circuit 83 in the embodiment is a voltage value generated at both ends of the load 81 and measured by the voltmeter 80.

The determination circuit 82 included in the sensing circuit 72 is connected to the measurement circuit 83. Based on a change in the first physical amount measured by the measurement circuit 83, it is detected whether the conductor is touched on the second substrate 70 and a touch position is detected when the conductor is touched. In the embodiment, when the determination circuit 82 detects a change in the voltage value measured by the voltmeter 80, the determination circuit 82 determines that the conductor such as a finger is touched on the second substrate 70 near the position at which one group of the first electrodes 56 in the line form selected by the first selection circuit 74 crosses one group of the second electrodes 58 in the line form selected by the second selection circuit 76 at timing at which the voltage value is changed.

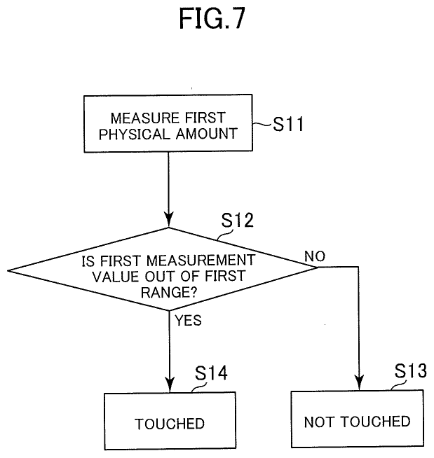

FIG. 7 is a diagram illustrating a flow of touch sensing of the display device 100 according to the embodiment. First, in measurement step S11 of the first measurement amount, the measurement circuit 83 illustrated in FIG. 6 measures a first measurement value of the first physical amount generated at the output end of the second selection circuit 76. In the embodiment, the measurement circuit 83 includes the load 81 and the voltmeter 80 connected to both ends of the load 81. The voltmeter 80 measures a voltage value which is the first physical amount. A measurement result by the voltmeter 80 is the first measurement value.

Subsequently, in measurement step S12 by the determination circuit, the determination circuit 82 determines whether the first measurement value measured by the measurement circuit 83 is out of a predetermined first range. The first range is a range in which an error is considered in a design value when a conductor such as a finger is not touched on the second substrate 70.

Then, when the first measurement value is out of the first range, the determination circuit 82 determines in measurement step S14 that the conductor such as a finger is touched on the second substrate 70 near a position selected by the first selection circuit 74 and the second selection circuit 76.

Conversely, when the first measurement value is within the first range, the determination circuit 82 determines in measurement step S13 that the conductor such as a finger is not touched on the second substrate 70 near a position selected by the first selection circuit 74 or the second selection circuit 76.

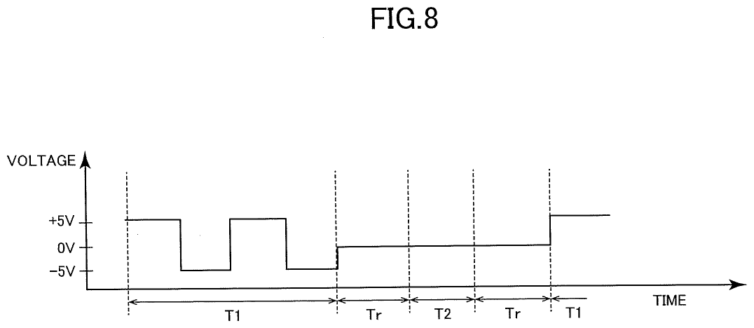

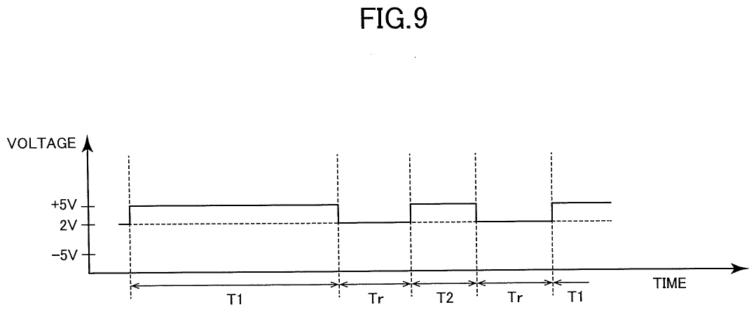

Hereinafter, touch sensing of the display device 100 according to the embodiment will be described in more detail with reference to FIGS. 8 and 9. FIG. 8 is a timing chart of an input voltage from the pulse generator in the display device 100 according to the embodiment. FIG. 9 is a timing chart of a first measurement value by the measurement circuit 83 in the display device 100 according to the embodiment. In the embodiment, as illustrated in FIGS. 8 and 9, a first period T1 which is a detection period of a touch position of the conductor in the plane direction in the first substrate 10 and a second period T2 which is a detection period of strength of a pressing force applied in the lamination direction of the display device 100 are alternately provided. A refresh period Tr is provided between the first period T1 and the second period T2.

As illustrated in FIG. 8, during the first period T1 which is a detection period of a touch position of the conductor in the plane direction in the first substrate 10, a pulse voltage of positive or negative 5 V is applied from the pulse generator 78 to one group of the first electrodes 56 in the line form selected by the first selection circuit 74.

When the conductor such as a finger is touched on the second substrate 70 near the second electrode 58 crossing one group of the first electrodes 56 in the line form selected by the first selection circuit 74 in one group of the second electrodes 58 in the line form selected by the second selection circuit 76 during the first period T1, the first measurement value measured by the measurement circuit 83 is changed. In the embodiment, as illustrated in FIG. 9, a voltage value measured by the voltmeter 80 connected to both ends of the load 81 connected to the output end of the second selection circuit 76 increases from 2 V to 5 V. When a dielectric body such as a finger is not touched at a portion selected by the first selection circuit 74 or the second selection circuit 76, as indicated by a dotted line in FIG. 9, a voltage value of about 2 V is normally measured by the voltmeter 80.

The determination circuit 82 receiving the first measurement value which is a measurement result from the measurement circuit 83 determines in determination step S12 by the determination circuit illustrated in FIG. 7 whether the first measurement value is out of the first range. In the embodiment, for example, it is determined whether a voltage value which is a measurement result of the voltmeter 80 included in the measurement circuit 83 is greater than a predetermined value, for example, is greater than 3 V. When the measurement result of the voltmeter 80 is equal to or greater than 3 V, the determination circuit 82 determines in detection step S14 that the first measurement value is out of the first range. Then, the determination circuit 82 detects that the conductor such as a finger is touched on the second substrate 70 near the position at which one group of the first electrodes 56 in the line form selected by the first selection circuit 74 crosses one group of the second electrodes 58 in the line form selected by the second selection circuit 76. When the measurement value of the voltmeter 80 is less than 3 V, the determination circuit 82 determines in detection step S13 that the first measurement value is within the first range. Then, the determination circuit 82 detects that the conductor such as a finger is not touched on the second substrate 70 near the position at which one group of the first electrodes 56 in the line form selected by the first selection circuit 74 crosses one group of the second electrodes 58 in the line form selected by the second selection circuit 76.

Next, a method of detecting strength of a pressing force applied in the lamination direction of the display device 100 will be described. FIG. 10 is a sectional view illustrating a state in which the second substrate 70 of the display device 100 according to the embodiment is pressed with an input body such as a finger. The piezoelectric layer 90 is compressed via the second substrate 70 by a pressing force by a finger.

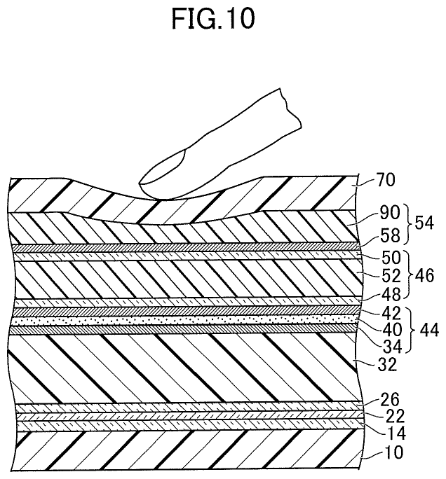

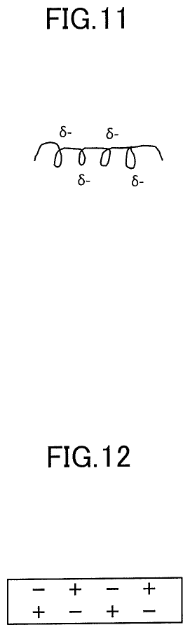

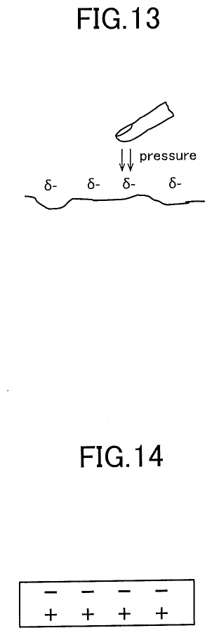

Here, the piezoelectric layer 90 is formed of an organic piezoelectric material such as polyvinylidene fluoride (PVDF), trifluorinated ethylene (TrFE), and polylactic acid (PLA), as described above. A molecular chain of the organic piezoelectric material takes a helical structure, as illustrated in FIG. 11, and charging arises on both sides of the molecular chain. At this time, as illustrated in FIG. 12, polarity is electrically negated on the entire upper surface and the entire lower surface of the piezoelectric layer 90. Therefore, the entire piezoelectric layer 90 is in a state similar to an uncharged state. However, as illustrated in FIG. 13, when an external pressure is added from, for example, the upper side of the piezoelectric layer 90, the molecular chain is stretched and charges concentrate on, for example, the upper surface side of the molecular chain. At this time, as illustrated in FIG. 14, the entire upper surface of the piezoelectric layer 90 is negatively charged, the entire lower surface of the piezoelectric layer 90 is positively charged, and thus the entire piezoelectric layer 90 is polarized. When the conductor is touched in the piezoelectric layer 90 in the charged state, a difference in the charges is negated, and therefore a current is generated.

When the upper surface and the lower surface of the piezoelectric layer 90 are disposed oppositely, the entire upper surface is positively charged and the lower surface is negatively charged. The present invention is not particularly limited to the positively or negatively charged upper surface and lower surface of the piezoelectric layer 90.

Due to the reason described with reference to FIGS. 11 to 14, the piezoelectric layer 90 compressed by the pressing force by the input body such as a finger, as illustrated in FIG. 10, is polarized and changed. The second electrodes 58 come into contact with the lower surface of the charged piezoelectric layer 90. Accordingly, a current generated by a piezoelectric effect in the piezoelectric layer 90 is output to the output end of the second selection circuit 76 via the second electrodes 58.

In the embodiment, as illustrated in FIG. 8, as described above, the second period T2 which is a detection period for the strength of the pressing force applied in the lamination direction of the display device 100 is provided after the refresh period Tr subsequent to the first period T1. During the refresh period Tr and the second period T2, a pulse voltage from the pulse generator 78 is not applied to the first selection circuit 74 and the first electrode 56.

When the piezoelectric layer 90 is compressed by a pressing force by a finger, as illustrated in FIG. 10, during the second period T2, a current generated by the piezoelectric effect in the piezoelectric layer 90 is output from the output end of the second selection circuit 76 and a change in the first physical amount based on an increase in the current value is measured by the measurement circuit 83. In the embodiment, the measurement circuit 83 includes the load 81 connected to the output end of the second selection circuit 76 and the voltmeter 80 connected to both ends of the load 81. Therefore, as illustrated in FIG. 9, a voltage is generated in the load 81 in accordance with the current value output from the output end of the second selection circuit 76. The voltage value is measured as a second measurement value by the voltmeter 80.

In accordance with magnitude of the second measurement value measured by the measurement circuit 83, the determination circuit 82 detects the strength of the pressing force by the input body such as a finger.

In the above-described configuration, the touch sensor 54 including the electrode-formed layer including the first electrode 56 and the second electrode 58 and the piezoelectric layer 90 can detect a touch position of the conductor such as a finger in the plane direction in the first substrate 10 and the strength of a pressing force applied in the lamination direction of the display device 100. As a result, it is possible to slim the display device 100.

In the configuration according to the embodiment, when the strength of a pressing force applied in the lamination direction of the display device 100 is detected, a voltage generated by the piezoelectric layer 90 is detected. Therefore, for example, even when parasitic capacitance occurs in the sealing layer 46, the parasitic capacitance does not affect detection precision of the voltage generated by the piezoelectric layer 90. Therefore, it is possible to perform more precise detection.

In the embodiment, the plurality of first electrodes 56 are connected to the first selection circuit 74 and the plurality of second electrodes 58 are connected to the second selection circuit 76. However, the plurality of first electrodes 56 may be connected to the second selection circuit 76 and the plurality of second electrodes 58 may be connected to the first selection circuit 74. In this case, a pulse voltage from the pulse generator 78 is applied to one group of the plurality of second electrodes 58 in the line form selected by the first selection circuit 74 and an output from one group of the plurality of first electrodes 56 in the line form selected by the second selection circuit 76 is measured by the measurement circuit 83.

The display device 100 is not limited to an organic electroluminescence display device and may be a display device in which each pixel includes a light-emitting element such as a quantum-dot light emitting diode (QLED) or may be a liquid crystal display device.

The present invention is not limited to the above-described embodiment and can be modified in various forms. For example, the configuration described in the embodiment can be substituted with substantially the same configuration, a configuration in which the same operational effects are obtained, or a configuration in which the same purpose can be attained.

It is construed, of course, in the present invention that other operational effects in the aspect described in the embodiment are apparent from the description of the present specification or can be appropriately predicted by those skilled in the art.

What is claimed is:

1. A display device comprising:
a first substrate;
a light-emitting element that is disposed above the first substrate;
an insulation layer that has an insulation surface provided above the light-emitting element; and
a touch sensor that is provided on an upper surface of the insulation surface,
wherein the touch sensor includes
a plurality of first electrodes that is provided on the upper surface of the insulation surface,
a plurality of second electrodes that is provided on the upper surface of the insulation surface and forms first electrostatic capacitance along with the plurality of first electrodes,
a piezoelectric layer that is provided on upper surfaces of the plurality of first electrodes and the plurality of second electrodes and is charged in accordance with application of a pressing force,
a pulse generator that applies a pulse voltage to the first electrodes, and
a determination circuit that detects a change in the first electrostatic capacitance from a change in a first measurement value related to the second electrodes and caused by the application of the pulse voltage and detects strength of the pressing force from a change in a second measurement value related to the second electrodes and not caused by the application of the pulse voltage.

2. The display device according to claim 1, wherein the plurality of first electrodes include a plurality of groups of the first electrodes in a line form connected in a first direction on a plane formed by the first substrate.

3. The display device according to claim 2, further comprising:
a first selection circuit disposed between the plurality of first electrodes and the pulse generator,
wherein the first selection circuit selects one group in order among the plurality of groups of the first electrodes in the line form and applies the pulse voltage from the pulse generator to the selected group of the first electrodes in the line form.

4. The display device according to claim 2, wherein in the groups of the first electrodes in the line form connected in the first direction, two first electrodes adjacent to one another are connected by a first connection portion.

5. The display device according to claim 2, wherein the plurality of second electrodes include a plurality of groups of the second electrodes in a line form connected in a second direction intersecting the first direction on a plane formed by the first substrate.

6. The display device according to claim 5, further comprising:
a second selection circuit disposed between the plurality of second electrodes and the determination circuit,
wherein the second selection circuit selects one group in order among the plurality of groups of the second electrodes in the line form and transfers a change in a physical amount output from the selected group of the second electrodes in the line form to the determination circuit.

7. The display device according to claim 5, wherein in the groups of the second electrodes in the line form connected in the second direction, two second electrodes adjacent to one another are connected by a second connection portion.

8. The display device according to claim 6, further comprising:
a second substrate that is provided above the touch sensor,
wherein the determination circuit detects a position of an input body formed from a conductor touched on the second substrate on the plane formed by the first substrate from a selection situation of the first selection circuit, a selection situation of the second selection circuit, and the change in the first measurement value and detects strength of a pressing force of the input body on the second substrate from the change in the second measurement value.

9. The display device according to claim 1,
wherein the first and second measurement values are measured by delaying a timing, and
wherein the pulse generator applies the pulse voltage to the first electrodes when the first measurement value is measured, and the pulse generator does not apply the pulse voltage to the first electrodes when the second measurement value is measured.

10. The display device according to claim 1, wherein the piezoelectric layer includes at least one of polyvinylidene fluoride, trifluorinated ethylene, and polylactic acid as a constituent material.

11. The display device according to claim 1, further comprising:
a bank that is provided on a lateral surface of the light-emitting element,
wherein a space between the first and second electrodes is located above the bank.

12. The display device according to claim 1, further comprising:
a sealing layer that includes at least an inorganic insulation layer above a plurality of the light-emitting elements,
wherein an upper surface of the sealing layer forms the insulation surface.

13. The display device according to claim 1, further comprising:
a display region in which the light-emitting element is provided,
wherein the piezoelectric layer is provided across an entire surface of the display region.
